(19) United States
(12) Patent Application Publication
(10) Pub. No.: US 2009/0295420 A1
(43) Pub. Date: Dec. 3, 2009

(54) SEMICONDUCTOR DEVICE AND TESTING METHOD

(75) Inventor: Hiroshi SHIBA, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Tokyo (JP)

(21) Appl. No.: 12/473,566

(22) Filed: May 28, 2009

(30) Foreign Application Priority Data
May 29, 2008 (JP) 2008-140608

(51) Int. Cl. G01R 31/26; G01R 31/02

(52) U.S. Cl. 324/763; 324/769

(57) ABSTRACT

A semiconductor device, comprising: a wafer; a radio receiving circuit chip that is formed on the wafer, and receives electric power and a test start signal transmitted by radio from outside; and a plurality of non-volatile memory chips that are formed on the wafer and respectively have self-diagnosis test circuits mounted thereon, wherein, in a test in a wafer state, in response to supply of the electric power and the test start signal from the radio receiving circuit chip through an interchip interconnection, all of the non-volatile memory chips on the wafer simultaneously execute tests by the self-diagnosis test circuits, and respectively write results of the tests into their own memory areas.

### CROSS-REFERENCE TO RELATED APPLICATION

This application is based on and claims the benefit of priority from the prior Japanese Patent Application No. 2008-140608, filed on May 29, 2008, the entire contents of which are incorporated herein by reference.

### BACKGROUND OF THE INVENTION

1. Field of the Invention

The present invention relates to a semiconductor device and a testing method.

2. Description of the Related Art

In general, non-volatile memory devices such as flash memories are subjected to the following tests: a non-defective chip selection test on the devices in a wafer state; a burn-in stress test on the devices already assembled into packages; and a final shipping test. In these tests, the device in a wafer state is tested by bringing a prove pin into contact with a pad on a chip of the device; and the device assembled into a package is tested by inserting the package into a socket, and then by bringing a package pin into contact with a terminal of the socket. For this reason, in each of these tests, there is fear that a poor contact may result in reduced test reliability.

To address this issue, there have been heretofore proposed: a semiconductor integrated circuit which are provided with a testing unit and a radio interface module to allow a non-contact test through radio communications; and a testing system performing such a non-contact test on a chip basis (for example, Japanese Patent Application Publication No. 2007-78407). The testing unit performs a self diagnosis test on an internal circuit, and the radio interface module inputs test information to this testing unit from the outside and outputs test information from this testing unit to the outside through radio communications.

However, a chip size of the above-described semiconductor integrated circuit increases since the radio interface module is provided to each chip. This causes a problem that a chip cost increases. This problem is more serious particularly for products, such as a flash memory, where cost-competitiveness is important.

Additionally, the testing system in the above-described proposal has another problem that testing efficiency in a mass production test is low since the system can test only one chip at a time.

### SUMMARY OF THE INVENTION

According to an aspect of the present invention, there is provided a semiconductor device, comprising: a wafer; a radio receiving circuit chip that is formed on the wafer, and receives electric power and a test start signal transmitted by radio from outside; and a plurality of non-volatile memory chips that are formed on the wafer and respectively have self-diagnosis test circuits mounted thereon, wherein, in a test in a wafer state, in response to supply of the electric power and the test start signal from the radio receiving circuit chip through an interchip interconnection, all of the non-volatile memory chips on the wafer simultaneously execute tests by the self-diagnosis test circuits, and respectively write results of the tests into their own memory areas.

According to another aspect of the present invention, there is provided a semiconductor device, comprising: a radio receiving circuit chip that receives electric power and a test start signal transmitted by radio from outside; a plurality of non-volatile memory chips that respectively have self-diagnosis test circuits mounted thereon; and a package in which the radio receiving circuit chip and the non-volatile memory chips are packaged, wherein, in a test in a packaged state, in response to supply of the electric power and the test start signal from the radio receiving circuit chip, the non-volatile memory chips execute tests by the self-diagnosis test circuits, and respectively write results of the tests into their own memory areas.

According to another aspect of the present invention, there is provided a testing method for a semiconductor device that includes a radio receiver and a plurality of non-volatile memory chips that respectively have self-diagnosis test circuits mounted thereon, the testing method comprising the steps of: transmitting electric power and a test start signal to the semiconductor device by radio; the radio receiver receiving the electric power and the test start signal; the radio receiver supplying the electric power and the test start signal to the non-volatile memory chips; the non-volatile memory chips executing tests by the self-diagnosis test circuits; the non-volatile memory chips writing results of the tests into their own memory areas; and, reading out the results of the tests from the memory areas, and judging whether each of the non-volatile memory chips is non-defective or defective.

### BRIEF DESCRIPTION OF THE DRAWINGS

FIG. 1 is a schematic view showing an example of an array of chips on a wafer for a semiconductor device according to Embodiment 1 of the present invention.

FIG. 2 is a schematic view showing an example of a configuration of a non-volatile memory of Embodiment 1 of the present invention.

FIG. 3 is a view showing a condition when the semiconductor device according to Embodiment 1 of the present invention is tested in a wafer state.

FIG. 4 is a schematic cross-sectional view showing an example of packaging of a semiconductor device according to Embodiment 2 of the present invention.

FIG. 5 is a schematic view showing a condition when the semiconductor device according to Embodiment 2 of the present invention is tested in a packaged state.

FIG. 6 is a flowchart showing a flow of processing in a testing method according to Embodiment 3 of the present invention.

### DESCRIPTION OF THE PREFERRED EMBODIMENTS

Embodiments of the present invention will be described below with reference to the drawings.

### Embodiment 1

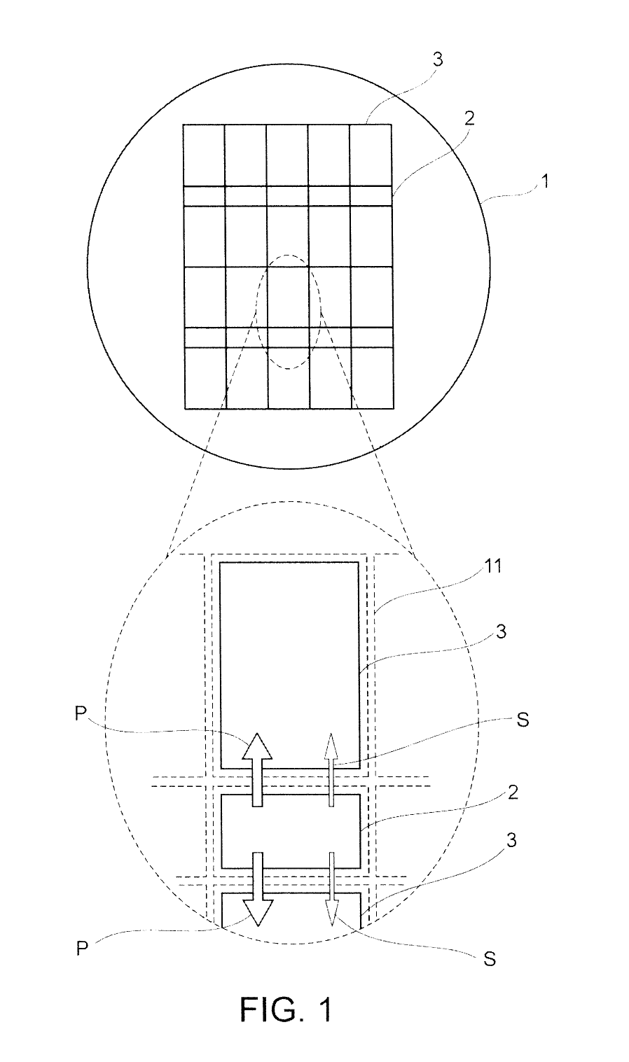

FIG. 1 is a schematic view showing an example of an array of chips on a wafer for a semiconductor device according to Embodiment 1 of the present invention.

A wafer 1 of this embodiment has radio receiving circuit chips 2 and non-volatile memory chips 3 mounted in combination on that single wafer. The radio receiving circuit chips 2 receive electric power and a test start signal that are transmitted from the outside by radio. Each of the non-volatile memory chips 3 has a self-diagnosis test circuit mounted thereon.

The radio receiving circuit chips 2 receive a test start signal for the self-diagnosis test circuits mounted on the non-volatile memory chips 3 at the same time as generating, from an electromagnetic wave transmitted from the outside, electric power through electromagnetic induction.

Each of the radio receiving circuit chip 2 supplies, through an interconnection intersecting a scribe line 11, generated electric power P and a received test start signal S to the non-volatile memory chips 3 that are arranged next to the radio receiving circuit chip 2. In this embodiment, an example will be shown in which each of the radio receiving circuit chips 2 supplies the electric power P and the test start signal S to two of the non-volatile memory chips 3 that are arranged above and below the radio receiving circuit chip 2.

Each of the non-volatile memory chips 3 retains, even after a power supply is cut off, data once written into a memory area thereof.

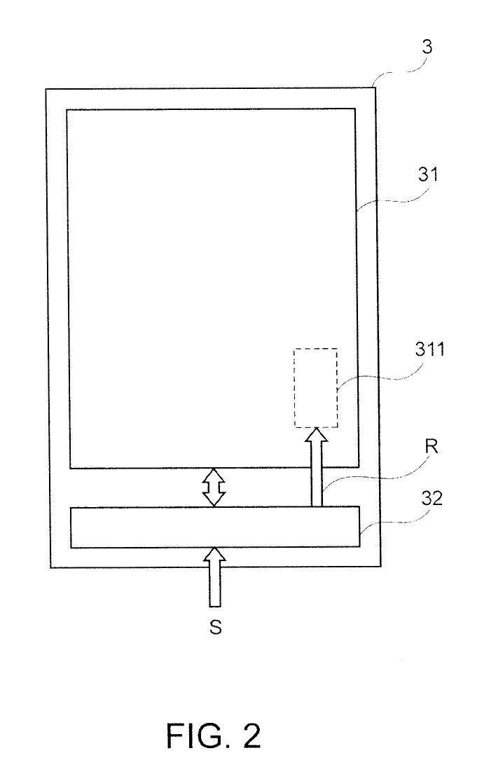

FIG. 2 is a schematic view showing an internal configuration of the non-volatile memory chip 3.

The non-volatile memory chip 3 includes a memory area 31, and a BIST (Built-in Self Test) circuit 32 that performs a self-diagnosis test with respect to operations inside the chip.

Once the test start signal S is inputted to the BIST circuit 32 from the outside, the BIST circuit 32 performs the test with respect to the operations inside the chip, judges whether or not the operations are normal, and stores a result of the judgment as a test result R into a test result storing area 311 provided in the memory area 31.

Since the test result R is thus stored in the test result storing area 311 which is a non-volatile memory area, the test result R is retained in the non-volatile memory chip 3 even if the power supply of the non-volatile memory chip 3 is cut off after the test is completed.

Next, testing of the semiconductor device of this embodiment will be described.

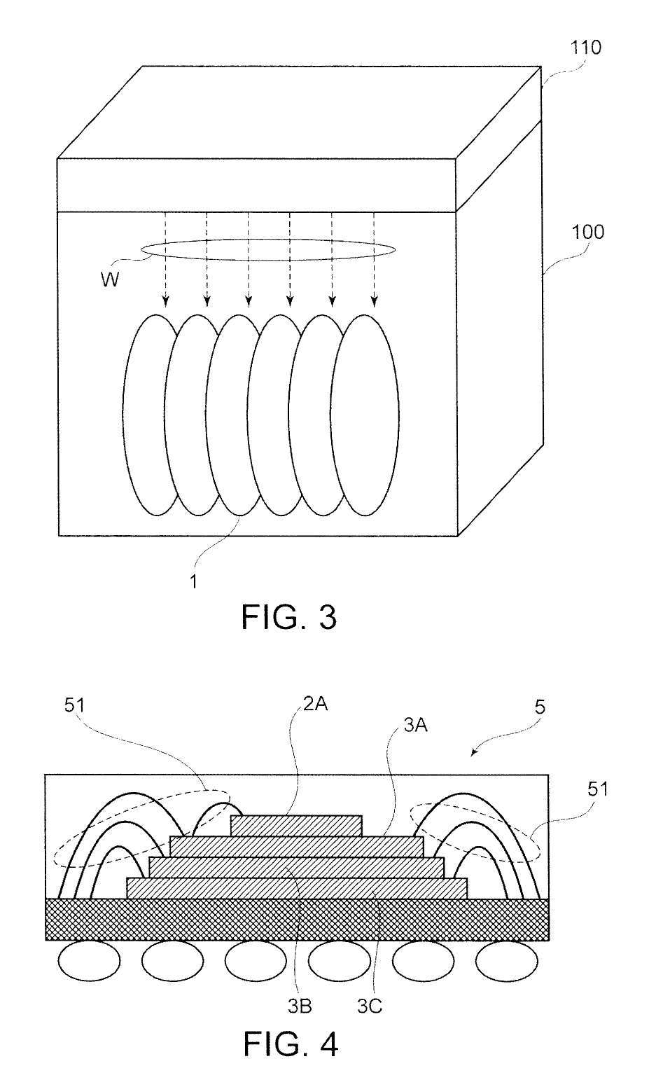

FIG. 3 is a view showing a condition when the semiconductor device of this embodiment is tested in a wafer state. FIG. 3 shows an example of when plural wafers 1 are simultaneously tested.

The plural wafers 1 are placed in line inside a test apparatus 100. The test apparatus 100 has a radio transmitter 110, and radiates an electromagnetic wave W toward the plural wafers 1 from the radio transmitter 110, thereby transmitting electric power and a test start signal by radio.

In response to this transmission of the electronic power and the test start signal by radio, all of the radio receiving circuit chips 2 mounted on each of the plural wafers 1 each supply the electronic power P and the test start signal S to the non-volatile memory chips 3 that are arranged above and below the radio receiving circuit chip 2.

In response to this supply of the electronic power P and the test start signal S, all of the non-volatile memory chips 3 mounted on each of the plural wafers 1 simultaneously execute the self-diagnosis tests using the BIST circuits 32 embedded therein, and store the test results R thereof into the test result storing areas 311 in the memory areas 31.

In that manner, non-contact tests on all of the non-volatile memory chips 3 mounted on each of the plural wafers 1 are simultaneously performed.

Here, if the test apparatus 100 is configured to be an apparatus having a temperature adjustment function, a burn-in stress test at a high temperature can also be executed.

According to the embodiment described above, function tests, burn-in stress tests or the like on plural non-volatile memory chips in a wafer state can be simultaneously performed in a non-contact manner without having radio receiving circuits provided to the respective chips. Thereby, testing efficiency in the mass-production of the chips can be considerably improved.

### Embodiment 2

FIG. 4 is a schematic cross-sectional view showing an example of packaging of a semiconductor device according to Embodiment 2 of the present invention.

In a package 5 in this embodiment, a radio receiving circuit chip 2A, and three non-volatile memory chips 3A, 3B and 3C are mounted in combination. The radio receiving circuit chip 2A receives electric power and a test start signal that are transmitted from the outside by radio, and each of the three non-volatile memory chips 3A, 3B and 3C has a self-diagnosis test circuit mounted thereon.

Note that the number of non-volatile memory chips mounted together in one package is not limited to three, and may be any number not less than two.

The radio receiving circuit chip 2A receives a test start signal for the self-diagnosis test circuits of the non-volatile memory chips 3A to 3C at the same time as generating, from an electromagnetic wave transmitted from the outside, electric power through electromagnetic induction.

The radio receiving circuit chip 2A supplies, through bonding wires 51, generated electric power P and a received test start signal S to the non-volatile memory chips 3A to 3C arranged in a stacked fashion.

An internal configuration of each of the non-volatile memory chips 3A to 3C is the same as the internal configuration of each of the non-volatile memory chips 3 shown in FIG. 2.

In each of the non-volatile memory chips 3A to 3C also, once the test start signal S is inputted to a BIST circuit 32 from the outside, the BIST circuit 32 performs a test with respect to operations inside the chip, and stores a test result R thereof into a test result storing area 311 provided in a memory area 31.

Next, testing of the semiconductor device of this embodiment will be described.

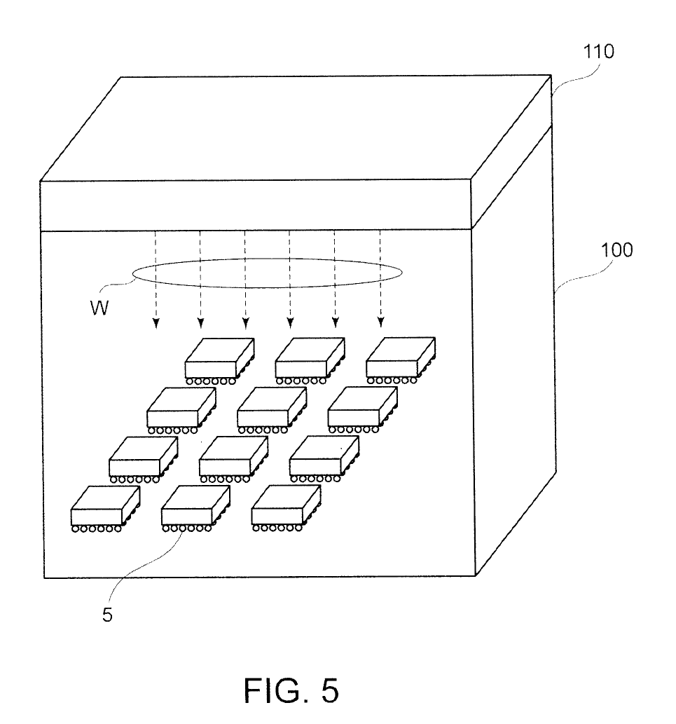

FIG. 5 is a view showing a condition when the semiconductor device according to this embodiment in a packaged state is tested. FIG. 5 shows an example of when plural packages 5 are simultaneously tested.

The plural packages 5 are placed in line in the same test apparatus 100 as shown in FIG. 3. The test apparatus 100 radiates an electromagnetic wave W toward the plural packages 5 from a radio transmitter 110, thereby transmitting electronic power and a test start signal by radio.

In response to this transmission of the electronic power and the test start signal by radio, the radio receiving circuit chips 2A mounted in the respective plural packages 5 each supply the electronic power P and the test start signal S to the non-volatile memory chips 3A to 3C mounted together in the same package as the radio receiving circuit chip 2A.

In response to this supply of the electric power P and the test start signal S, the non-volatile memory chips 3A to 3C mounted in each of the plural packages 5 simultaneously execute the self-diagnosis tests using the BIST circuits 32 embedded therein, and store the test results R thereof into the test result storing areas 311 in the memory areas 31.

In that manner, non-contact tests on the non-volatile memory chips 3A to 3C mounted in each of the plural packages 5 are simultaneously performed.

Here, if the test apparatus 100 is configured to be an apparatus having a temperature adjustment function, burn-in stress tests at a high temperature can also be executed.

According to the embodiment described above, function tests, burn-in stress tests or the like on plural non-volatile memory chips in a packaged state can be simultaneously performed in a non-contact manner without having radio receiving circuits provided to the respective chips. Thereby, testing efficiency in the mass-production of the chips can be considerably improved.

### Embodiment 3

In this embodiment, an example of a testing method will be shown in which, after a non-volatile memory chip stored in the semiconductor device of Embodiment 1 or 2 is tested, a judgment is made as to whether the non-volatile memory chip is non-defective or defective.

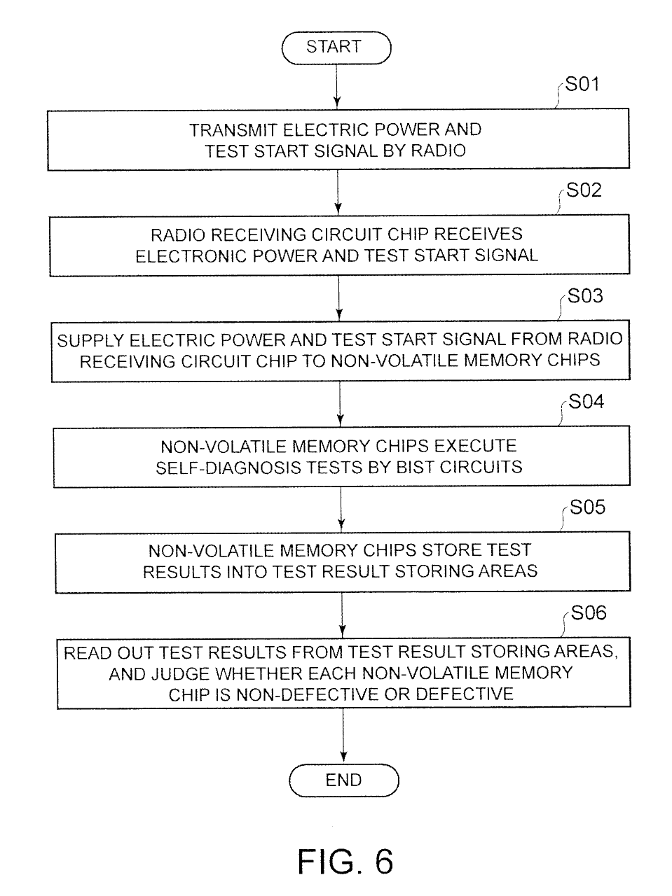

FIG. 6 is a flowchart showing a flow of processing in the testing method of this embodiment.

When testing is started, electric power and a test start signal are transmitted by radio to the wafers 1 in Embodiment 1 or to the packages 5 in Embodiment 2, for example, by use of the testing apparatus 100 shown in FIGS. 3 and 5 (step S01).

In response to this transmission, each of the radio receiving circuit chips 2 mounted on the wafers 1, or each of the radio receiving circuit chips 2A mounted in the packages 5 receives the electronic power and the test start signal (step S02).

The radio receiving circuit chip 2 supplies to corresponding ones of the non-volatile memory chips 3, or the radio receiving circuit chip 2A supplies to corresponding ones of the non-volatile memory chips 3A to 3C, the electronic power P and the test start signal S (step S03).

In response to this supply of the electric power P and the test start signal S, the non-volatile memory chips 3 or the non-volatile memory chips 3A to 3C execute the self-diagnosis tests using the BIST circuits 32 (step S04).

Upon completion of the self-diagnosis tests, the non-volatile memory chips 3 or the non-volatile memory chips 3A to 3C store the test results R thereof into the test result storing areas 311 in the memory areas 31 of the respective chips (step S05).

Then, the wafers 1 or the packages 5 are taken out from the test apparatus 100. Although power supplies to the non-volatile memory chips 3 or the non-volatile memory chips 3A to 3C are thereby cut off, the test results R stored in the test result storing areas 311 in the memory areas 31 of the respective chips are retained as they are.

Thereafter, the test results R stored in the test result storing areas 311 are read out by use of a usual testing apparatus such as an LSI tester. Thereby, a judgment is made as to whether each of the non-volatile memory chips 3 or non-volatile memory chips 3A to 3C is non-defective or defective (step S06).

The above step is the end of the testing according to this flow.

In this embodiment, a usual testing apparatus is thus used in the judgment as to whether the chip is non-defective or defective. However, the use of the testing apparatus is only for reading out the test results R of the self-diagnosis test on the non-volatile memory chips, and thus requires only a very short time.

According to the embodiment described above, each of plural non-volatile memory chips in a wafer state or each of plural non-volatile memory chips mounted in packages can be judged in a short time as to whether it is non-defective or defective. Thereby, testing efficiency in the mass-production of the chips can be improved.

Note that the testing method of this embodiment is applicable not only to semiconductor devices, such as those shown in Embodiments 1 and 2, in each of which radio receiving circuits are mounted in chips different from non-volatile memory chips, but also to semiconductor devices in each of which radio receiving circuits are mounted in non-volatile memory chips.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor device, comprising:
a wafer;
a radio receiving circuit chip that is formed on the wafer, and receives electric power and a test start signal transmitted by radio from outside; and
a plurality of non-volatile memory chips that are formed on the wafer and respectively have self-diagnosis test circuits mounted thereon,
wherein, in a test in a wafer state, in response to supply of the electric power and the test start signal from the radio receiving circuit chip through an interchip interconnection, all of the non-volatile memory chips on the wafer simultaneously execute tests by the self-diagnosis test circuits, and respectively write results of the tests into their own memory areas.

2. The semiconductor device according to claim 1, wherein
the electric power and the test start signal are simultaneously transmitted by radio to a plurality of the wafers, and
the non-volatile memory chips mounted on each of the wafers are simultaneously tested.

3. The semiconductor device according to claim 1, wherein,
the radio receiving circuit chip and each of the non-volatile memory chips are arranged next to each other with a scribe line interposed therebetween on the wafer, and
the interchip interconnection intersects the scribe line.

4. The semiconductor device according to claim 1, wherein a plurality of the radio receiving circuit chips are formed on the wafer.

5. The semiconductor device according to claim 4, wherein each of the radio receiving circuit chips supplies the electric power and the test start signal to the non-volatile memory chips.

6. A semiconductor device, comprising:
a radio receiving circuit chip that receives electric power and a test start signal transmitted by radio from outside;
a plurality of non-volatile memory chips that respectively have self-diagnosis test circuits mounted thereon; and
a package in which the radio receiving circuit chip and the non-volatile memory chips are packaged,
wherein, in a test in a packaged state, in response to supply of the electric power and the test start signal from the radio receiving circuit chip, the non-volatile memory chips execute tests by the self-diagnosis test circuits, and respectively write results of the tests into their own memory areas.

7. The semiconductor device according to claim 6, wherein
the electric power and the test start signal are simultaneously transmitted by radio to a plurality of the packages, and
the non-volatile memory chips mounted in all of the packages are simultaneously tested.

8. The semiconductor device according to claim 6, wherein the radio receiving circuit chip and the non-volatile memory chips are stacked on one another inside the package.

9. The semiconductor device according to claim 8, further comprising a bonding wire that connects the radio receiving circuit chip to the non-volatile memory chips, and transfers the electric power and the test start signal.

10. A testing method for a semiconductor device that includes a radio receiver and a plurality of non-volatile memory chips that respectively have self-diagnosis test circuits mounted thereon, the testing method comprising the steps of:
transmitting electric power and a test start signal to the semiconductor device by radio;
the radio receiver receiving the electric power and the test start signal;
the radio receiver supplying the electric power and the test start signal to the non-volatile memory chips;
the non-volatile memory chips executing tests by the self-diagnosis test circuits;
the non-volatile memory chips writing results of the tests into their own memory areas; and,
reading out the results of the tests from the memory areas, and judging whether each of the non-volatile memory chips is non-defective or defective.

11. The testing method according to claim 10, wherein
the electric power and the test start signal are simultaneously transmitted by radio to a plurality of the semiconductor devices, and
the non-volatile memory chips mounted in all of the semiconductor devices are simultaneously tested.

12. The testing method according to claim 10, wherein the radio receiver is a radio receiving circuit mounted inside each of the non-volatile memory chips.

13. The testing method according to claim 10, wherein the radio receiver is a radio receiving circuit chip provided outside the non-volatile memory chips.

14. The testing method according to claim 13, wherein the radio receiving circuit chip and the non-volatile memory chips are formed on one wafer.

15. The testing method according to claim 14, wherein,
the radio receiving circuit chip and each of the non-volatile memory chips are arranged next to each other with a scribe line interposed therebetween on the wafer, and
the electric power and the test start signal are supplied to the non-volatile memory chip through an interchip interconnection intersecting the scribe line.

16. The testing method according to claim 14, wherein a plurality of the radio receiving circuit chips are formed on the wafer.

17. The testing method according to claim 16, wherein each of the radio receiving circuit chips supplies the electric power and the test start signal to the non-volatile memory chips.

18. The testing method according to claim 13, wherein the radio receiving circuit chip and the non-volatile memory chips are formed within one package.

19. The testing method according to claim 18, wherein the radio receiving circuit chip and the non-volatile memory chips are stacked on one another inside the package.

20. The testing method according to claim 19, wherein the electric power and the test start signal are supplied to the non-volatile memory chips through a bonding wire connecting the radio receiving circuit chip to the non-volatile memory chips.
